(19) United States
(12) Patent Application Publication
(10) Pub. No.: US 2013/0264518 A1
(43) Pub. Date: Oct. 10, 2013

(54) SINGLET HARVESTING WITH ORGANIC MOLECULES FOR OPTOELECTRONIC DEVICES

(71) Applicant: Hartmut Yersin, Sinzing (DE)

(72) Inventor: Hartmut Yersin, Sinzing (DE)

(73) Assignee: Cynora GmbH, Eggenstein-Leopoldshafen (DE)

(21) Appl. No.: 13/806,948

(22) PCT Filed: Jun. 28, 2011
(86) PCT No.: PCT/EP2011/060834

§ 371 Date: Dec. 26, 2012

(30) Foreign Application Priority Data
Jun. 29, 2010 (DE) 10 2010 025 547.5

(51) Int. Cl. H01L 51/00

(52) U.S. Cl. CPC H01L 51/0072; H01L 51/0073; H01L 51/0071; H01L 51/0062; H01L 51/005; H01L 51/0074
USPC 252/301.16

(57) ABSTRACT

The invention relates to a composition comprising an organic emitter molecule, this molecule having a ΔE(S₁−T₁) value between the lowermost excited singlet state (S₁) and the triplet state beneath it (T₁) of less than 2500 cm⁻¹, and an optically inert atom or molecule for reducing the inter-system crossing time constant of the organic molecule to less than 10⁻⁶ s.

The present invention relates to the use of organic dyes as emitters in OLEDs (organic light-emitting diodes) and in other optoelectronic assemblies.

### INTRODUCTION

A dramatic change is currently on the horizon in the field of visual display and illumination technology. It will be possible to manufacture flat displays or illuminated surfaces having a thickness of less than 0.5 mm. These are notable for many fascinating properties. For example, it will be possible to achieve illuminated surfaces in the form of wallpaper with very low energy consumption. It is also of particular interest that color visual display units will be producible with hitherto unachievable colorfastness, brightness and viewing angle independence, with low weight and with very low power consumption. It will be possible to configure the visual display units as microdisplays or large visual display units of several square meters in area in rigid form or flexibly, or else as transmission or reflection displays. In addition, it will be possible to use simple and cost-saving production processes such as screen printing or inkjet printing or vacuum sublimation. This will enable very inexpensive manufacture compared to conventional flat visual display units. This new technology is based on the principle of the OLEDs, the organic light-emitting diodes. Furthermore, through the use of specific organic materials (molecules), many new optoelectronic applications are on the horizon, for example in the field of organic solar cells, organic field-effect transistors, organic photodiodes etc.

Particularly for the OLED sector, it is apparent that such assemblies are already now of economic significance, since mass production is expected shortly. Such OLEDs consist predominantly of organic layers which can also be manufactured flexibly and inexpensively. OLED components can also be configured with large areas as illumination bodies, but also in small form as pixels for displays.

Compared to conventional technologies, for instance liquid-crystal displays (LCDs), plasma displays or cathode ray tubes (CRTs), OLEDs have numerous advantages, such as a low operating voltage of a few volts, a thin structure of only a few hundred nm, high-efficiency self-illuminating pixels, high contrast and good resolution, and the possibility of representing all colors. In addition, in an OLED, light is produced directly on application of electrical voltage, rather than merely being modulated.

A review of the function of OLEDs can be found, for example, in H. Yersin, Top. Curr. Chem. 2004, 241, 1 and H. Yersin, “Highly Efficient OLEDs with Phosphorescent Materials”; Wiley-VCH, Weinheim, Germany, 2008.

Since the first reports regarding OLEDS (see, for example, Tang et al., Appl. Phys. Lett. 1987, 51, 913), these devices have been developed further particularly with regard to the emitter materials used, and particular interest has been attracted in the last few years by what are called triplet emitters or else phosphorescent emitters.

OLEDs are generally implemented in layer structures. For better understanding, FIG. 1 shows a basic structure of an OLED. Owing to the application of external voltage to a transparent indium tin oxide (ITO) anode and a thin metal cathode, the anode injects positive holes, and the cathode negative electrons. These differently charged charge carriers pass through intermediate layers, which may also consist of hole or electron blocking layers not shown here, into the emission layer. The oppositely charged charge carriers meet therein at or close to doped emitter molecules, and recombine. The emitter molecules are generally incorporated into matrices consisting of small molecules or polymer matrices (in, for example, 2 to 10% by weight), the matrix materials being selected so as also to enable hole and electron transport. The recombination gives rise to excitons (=excited states) which transfer their excess energy to the respective electroluminescent compound. This compound can then be converted to a particular electronic excited state which is then converted very substantially and with substantial avoidance of radiationless deactivation processes to the corresponding ground state by emission of light.

With a few exceptions, the electronic excited state, which can also be formed by energy transfer from a suitable precursor exciton, is either a singlet or triplet state. Since the two states are generally occupied in a ratio of 1:3 on the basis of spin statistics, the result is that the emission from the singlet state, which is referred to as fluorescence, according to the present state of the art, leads to maximum emission of only 25% of the excitons produced. In contrast, triplet emission, which is referred to as phosphorescence, exploits and converts all excitons and emits them as light (triplet harvesting), such that the internal quantum yield in this case can reach the value of 100%, provided that the additionally excited singlet state which is above the triplet state in terms of energy relaxes fully to the triplet state (intersystem crossing, ISC), and radiationless competing processes remain insignificant. Thus, triplet emitters, according to the current state of the art, are more efficient electroluminophores and have better suitability than purely organic singlet emitters for ensuring a high light yield in an organic light-emitting diode.

The triplet emitters suitable for triplet harvesting used are generally transition metal complexes in which the metal is selected from the third period of the transition metals. This predominantly involves very expensive noble metals such as iridium, platinum or else gold. (See also H. Yersin, Top. Curr. Chem. 2004, 241, 1 and M. A. Baldo, D. F. O'Brien, M. E. Thompson, S. R. Forrest, Phys. Rev. B 1999, 60, 14422).

The phosphorescent organometallic triplet emitters known to date in OLEDs, however, have a disadvantage, which is that the emission lifetime, which is in the region of a few microseconds, is relatively long. This gives rise to saturation effects with increasing current densities and the resulting occupation of a majority of or all emitter molecules. Consequently, further charge carrier streams can no longer lead completely to the occupation of the excited and emitting states. The result is then merely unwanted ohmic losses. As a result, there is a distinct decline in efficiency of the OLED device with rising current density (called “roll-off” behavior). The effects of triplet-triplet annihilation and of self-quenching are similarly unfavorable (see, for example, H. Yersin, “Highly Efficient OLEDs with Phosphorescent Materials”, Wiley-VCH, Weinheim 2008 and S. R. Forrest et al., Phys. Rev. B 2008, 77, 235215). For instance, disadvantages are found particularly in the case of use of emitters with long emission lifetimes for OLED illuminations where a high luminance, for example of more than 1000 cd/m², is required (cf.: J. Kido et al. Jap. J. Appl. Phys. 2007, 46, L10.). Furthermore, organometallic complexes in electronically excited states are frequently more chemically reactive than in the base states. This is generally caused by metal-ligand bond breakage. Therefore, the long-term stability of these emitter materials is inadequate in many cases. (T. Sajoto, P. I. Djurovich, A. B. Tamayo, J. Oxgaard, W. A. Goddard III, M. E. Thompson; J. Am. Chem. Soc. 2009, 131, 9813). As a result, efforts are being made to develop emitter molecules with no metal sites and with minimum emission lifetime, but nevertheless high emission quantum yield. OLEDs using such emitters then exhibit a much lesser extent of roll-off behavior in the efficiency, and additionally enable a longer lifetime of the optoelectronic device.

In summary, the prior art can be described such that the triplet emitters which are efficient per se and are known to date have the disadvantages that
expensive noble metal molecules have to be used and that
the emission lifetimes achievable using such molecules are quite long at a few microseconds, and thus exhibit the above-described roll-off behavior in efficiency
and that
these emitters formed on the basis of organometallic complexes have only inadequate long-term stability in many cases.

### DESCRIPTION OF THE INVENTION

Surprisingly, the problems described above can be significantly improved or solved by the present invention, using organic molecules (dyes, emitter molecules) which have particular electronic structures or singlet-triplet energy separations and which are modified in accordance with the invention by changes in the immediate environment of the emitters. This process of “singlet harvesting for organic emitters” which is proposed here for the first time is to be described briefly hereinafter using FIG. 2:

FIG. 2a shows a (simplified) energy level scheme for a typical, purely organic molecule having a ΔE(S₁−T₁ value between the lowermost excited singlet state (S₁) and the triplet state (T₁) below it of greater than 2500 cm⁻¹.

This scheme can be used to illustrate the photophysical electroluminescence properties of these molecules. Hole-electron recombination, as occurs, for example, in an optoelectronic component, leads, on statistical average, to 25% occupation of the singlet state and to 75% occupation of the three sub-states of the triplet state. Since the emission transition from the triplet state T₁ to the singlet state S₀ is strongly spin-forbidden in organic molecules due to the low level of spin-orbit coupling, the excitation energy which arrives at the triplet state is converted radiationlessly to heat and has thus been lost to the light production by electroluminescence. The occupied singlet state can, however, exhibit effective emission (fluorescence) because this is a spin-allowed singlet-singlet transition. In this context, it is important to mention that the radiationless relaxation process from the S₁ state to the T₁ state, called the intersystem crossing (ISC) process, is likewise strongly forbidden due to the low level of spin-orbit coupling. Otherwise, no fluorescence would be observable. For the time constants, this means that τ₁(ISC) is several orders of magnitude longer than the fluorescence lifetime, which is in the region of one to a few nanoseconds for τ(S₁).

According to the invention, the above-described disadvantages of the prior art can be avoided. This is possible by a combination of two steps:
I. Organic molecules with high emission quantum yield (greater than 50%) are provided, for which the energy difference between the singlet S₁ and the triplet T₁ is sufficiently small that thermal repopulation from the triplet T₁ to the singlet S₁ is possible at room temperature, as a result of which the triplet excitation can be converted to light via the singlet S₁ state. This is possible in accordance with the invention using purely organic molecules, for instance using organic molecules of the formulae I, II and III.
II. The extremely long intersystem crossing time constant (τ(ISC)) of purely organic molecules is shortened by a few orders of magnitude in order to enable sufficiently rapid thermal repopulation. This is possible by virtue of enhancement of spin-orbit coupling, more particularly by additional introduction of atoms or molecules which support a high level of spin-orbit coupling. This effect is known to the chemist as the “external heavy atom effect”. This process is explained further below.

Using these two strategies, which are to be used together—as illustrated by FIG. 2b—the triplet and singlet excitations populated in the electroluminescent excitation can be collected and converted to light via the singlet state S₁. This process exploiting the singlet harvesting effect for organic molecules, which is described here for the first time, is explained in detail hereinafter.

Accordingly, the invention, in one aspect, provides a composition, especially for utilization in an optoelectronic device, which comprises
an organic emitter molecule having a lowermost excited singlet state (S₁) and a triplet state (T₁) below it, the ΔE(S₁−T₁) value of the organic molecule being less than 2500 cm⁻¹, and
an optically inert atom or molecule which interacts with the organic molecule such that the intersystem crossing time constant of the organic molecule is reduced to less than 10⁻⁶ s, preferably to less than 10⁻⁸ s, more preferably to less than 10⁻⁹ s. In a preferred configuration, this can be accomplished by an optically inert atom or molecule which has, or molecular components which have, a high level of spin-orbit coupling. This can be described by the spin-orbit coupling constant, which should be higher than about 200 cm⁻¹, preferably higher than 1000 cm⁻¹ and more preferably higher than 2000 cm⁻¹, most preferably greater than 4000 cm⁻¹.

The terms “spin-orbit coupling constant” and “intersystem crossing time constant” are specialist terms which are commonly used in the photophysical literature and are therefore known to those skilled in the art.

### Molecules Having Small ΔE(S₁−T₁) Separations

FIG. 2b shows an energy level diagram for an organic molecule having a small energy difference ΔE(S₁−T₁)<2500 cm⁻¹. This energy difference is small enough to enable thermal repopulation of the S₁ state from the T₁ state according to a Boltzmann distribution, or according to the thermal energy k_{B}T, and hence thermally activated light emission from the S₁ state. This process is controlled by equation (1):

Int(S₁→S₀)/Int(T₁→S₀)=k(S₁)/k(T₁)exp(−ΔE/k_{B}T) (1)

In this equation, Int(S₁→S₀)/Int(T₁→S₀) is the intensity ratio of the emissions from the S₁ state and the T₁ state. k_{B} is the Boltzmann constant and T the absolute temperature. k(S₁)/k(T₁) is the rate ratio of the conversion processes from the singlet S₁ and from the triplet T₁ to the electronic ground state S₀. For organic molecules, this ratio is between 10⁷ and 10¹⁰. Preference is given in accordance with the invention to molecules having a rate ratio of about 10⁸, better of about 10⁹, more preferably of about 10¹⁰. ΔE represents the energy difference ΔE₂(S₁−T₁) according to FIG. 2b.

The process of thermal repopulation described opens up an emission channel via the singlet state S₁ from the populated triplet. Since the transition from the S₁ to the S₀ state is strongly allowed, the triplet excitation energy, which is otherwise lost is obtained virtually completely as light emission via the singlet state. At a given temperature, for example at room temperature, the smaller the energy difference ΔE, the more marked this effect is. Preference is therefore given to organic molecules having a ΔE=ΔE(S₁−T₁) value between the lowermost excited singlet state and the triplet state below it of less than 2500 cm⁻¹, better less than 1500 cm⁻¹, preferably of less than 1000 cm⁻¹.

This effect is to be illustrated by a numerical example. Given an energy difference of ΔE=1300 cm⁻¹, for room temperature applications (T=300 K) with k_{B}T=210 cm⁻¹ and a rate ratio of 10⁸, an intensity ratio of the singlet to triplet emission according to equation (1) of approx. 2·10⁵ is obtained. This means that the singlet emission process is dominant to an extreme degree for a molecule having these example values.

The emission lifetime of this example molecule also changes as a result. The thermal repopulation results in a mean lifetime τₐᵥ. This can be described by equation (2)

τₐᵥ≈τ(S₁)·exp(ΔE/k_{B}T) (2)

In this equation, τ(S₁) is the fluorescence lifetime without repopulation and τₐᵥ the emission lifetime which is determined on opening of the repopulation channel by the two states T₁ and S₁ (see FIG. 2b). The other parameters have been defined above.

Equation (2) is again to be illustrated by a numerical example. For the assumed energy difference of ΔE=1300 cm⁻¹ and a decay time of the fluorescing S₁ state of 1 ns, an emission decay time (of the two states, i.e. of the S₁ state thermally repopulated from the T₁ state) of τₐᵥ≈500 ns is obtained. This decay time is already much shorter than those of very good triplet emitters, the decay times of which are in the range from approx. 1.5 μs to 10 μs.

The applicability of equation (2) and the validity of the above-described calculation of the decay time τₐᵥ, in accordance with the invention, require the use of additives which increase spin-orbit coupling (for detailed arguments see, for example, below). These additives, i.e. optically inert atoms or molecules of the composition, interact with the organic emitter molecules such that the mean (av, thermalized) emission lifetime of the two states S₁ and T₁ of the organic molecule is reduced to about 500 ns. Preference is given to compositions of such a kind that the emission lifetime is reduced to less than 1 μs, preferably to less than 600 ns and more preferably to less than 200 ns.

In summary, using this “singlet harvesting process for organic molecules”, it is thus possible in the ideal case to capture virtually all, i.e. a maximum of 100%, of the excitons and convert them to light via singlet emission. In addition, it is possible to shorten the emission decay time well below the value for triplet emitters, which is a few microseconds. Therefore, the inventive composition is particularly suitable for optoelectronic components.

Organic molecules having the above-described properties, i.e. having a small singlet-triplet energy difference ΔE (S₁−T₁), are preferably organic molecules having the following general formulae I to III:

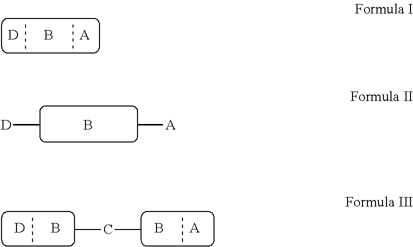

In these formulae, D is a chemical group or a substituent with electron-donating effect (D, donor effect). Substituents of this kind may be present once, twice or more than twice. They may be the same or different.

A is a chemical group or a substituent with electron-withdrawing propensity (A, acceptor effect). Substituents of this kind may be present once, twice or more than twice. They may be the same or different.

The base structure B is formed from conjugated organic groups which consist of aromatic, heteroaromatic and/or conjugated double bonds.

### Examples of Donors D:

—O(—), —N-alkyl group, —N-(alkyl group)₂ —NH₂, —OH, —O-alkyl group, —NH(CO)— alkyl group, —O(CO), -alkyl group, -alkyl group, -phenyl group, —(CH)═C—(alkyl group)₂

### Examples of Acceptors A:

-halogen, —(CO)H, —(CO)-alkyl group, —(CO)O-alkyl group, —(CO)OH, —(CO)Cl, —CF₃, —CN, —S(O)₂OH, —NH₃(+), —N(alkyl group)₃(+), N(O)₂

### Formation of the Base Structure B:

B is formed from conjugated organic groups which consist of aromatic, heteroaromatic and/or conjugated double bonds. Preference is given to molecular base structures B having aromatic or heteroaromatic rings smaller than 15, more preferably smaller than 10, most preferably smaller than seven. The aromatic or heteroaromatic rings are chemically joined directly or chemically bonded via alkenyl groups having conjugated double bonds smaller than 10, more preferably smaller than six and most preferably smaller than 3.

### Examples of Joining C Groups:

Preference is given to chemically bonded alkenyl groups having a number of conjugated double bonds of less than 10, more preferably less than 6 and most preferably less than 3.

The organic molecules described by formulae I to III have ΔE(S₁−T₁) values between the lowermost excited singlet state and the triplet state below it of less than 2500 cm⁻¹, preferably less than 1500 cm⁻¹ and more preferably less than 1000 cm⁻¹. Processes for measurement or calculation of the ΔE(S₁−T₁) values are discussed below.

Preference is given to organic molecules which, without use of additives, have a high fluorescence quantum yield from the S₁ state of greater than 50%, preferably greater than 70%, more preferably greater than 90% (determination with commercial measuring instruments for emission quantum yield) and for which the absorption intensities, i.e. the molar decadic extinction coefficients, of the transitions between the ground state S₀ and the excited state S₁ are greater than 10⁴ l/mol cm, preferably greater than 2×10⁴ l/mol cm, more preferably greater than 5×10⁴ l/mol cm (determination with commercial absorption spectrometers).

The invention relates, in a further aspect, to a process for selecting organic molecules for which the ΔE(S₁−T₁) value between the lowermost excited singlet state (S₁) and the triplet state (T₁) below it is less than 2500 cm⁻¹, preferably less than 1500 cm⁻¹, more preferably less than 1000 cm⁻¹.

The determination of the ΔE(S₁−T₁) value can either be performed by quantum-mechanical calculations using computer programs known in the prior art (for example using Turbomole programs executing TDDFT calculations with reference to CC2 calculations) or determined experimentally, as explained below.

The energy difference ΔE(S₁−T₁), more particularly of the organic molecules described by formulae I to III, can be described as an approximation by quantum-mechanical means via the exchange integral multiplied by a factor of 2. The value of the latter depends directly on the overlap of the molecular orbitals in the area on the D side of B with the molecular orbitals in the area on the A side of B. Due to the properties of D and A described above, these molecular orbitals are distributed over different spatial areas (partly delocalized over n or n* molecular orbitals). This means that an electronic transition between the different molecular orbitals represents a charge transfer (CT) process. The smaller the overlap of the above-described molecular orbitals, the more marked is the electronic charge transfer character. This is then associated with a decrease in the exchange integral and hence a decrease in the energy difference ΔE(S₁−T₁). In other words, ΔE(S₁−T₁) can be varied via the strengths of the electron-donating and -withdrawing substituents/groups of the organic molecule. Due to these photophysical (quantum-mechanical) properties, it is possible to achieve the inventive energy differences with ΔE(S₁−T₁) of less than 2500 cm⁻¹ or less than 1500 cm⁻¹ or less than 1000 cm⁻¹.

The ΔE(S₁−T₁) value can be determined experimentally as follows:

For a given organic molecule, the energy separation ΔE(S₁−T₁)=ΔE can be determined in a simple manner using the above-specified equation (1). A rearrangement gives:

ln{Int(S₁→S₀)/Int(T₁→S₀)}=ln{k(S₁)/k(T₁)}−(ΔE/k_{B})(1/T (3)

For the measurement of the intensities Int(S₁→S₀) and Int(T₁→S₀), it is possible to use any commercial spectrophotometer. A graphic plot of the (logarithmized) intensity ratios ln{Int(S₁→S₀)/Int(T₁→S₀)} measured at different temperatures against the reciprocal of the absolute temperature T generally gives a straight line. The measurement is conducted within a temperature range from room temperature (300 K) to 77 K or to 4.2 K, the temperature being established by means of a cryostat. The intensities are determined from the (corrected) spectra, Int(S₁→S₀) and Int(T₁→S₀) representing, respectively, the integrated fluorescence and phosphorescence band intensities, which can be determined by means of the programs provided with the spectrophotometer. The respective transitions (band intensities) can be identified easily since the triplet band is at lower energy than the singlet band and gains intensity with falling temperature. The measurements are conducted in oxygen-free dilute solutions (approx. 10⁻² mol L⁻¹) or on thin films of the corresponding molecule or on films doped with the corresponding molecules. If the sample used is a solution, it is advisable to use a solvent or solvent mixture which forms glasses at low temperatures, such as 2-methyl-THF, THF (tetrahydrofuran) or aliphatic hydrocarbons. If the sample used as a film, the use of a matrix having a much greater singlet and triplet energy than that of the organic emitter molecules, for example PMMA (polymethyl methacrylate), is suitable. This film can be applied from solution. It is particularly important that, as described below, the molecules to be analyzed are used with the respective additives.

The slope of the straight line is −ΔE/k_{B}. With k_{B}=1.380·10⁻²³ JK⁻¹=0.695 cm⁻¹ K⁻¹, it is possible to determine the energy separation directly.

Viewing this in an equivalent manner, it is found that it is also possible to determine the ΔE(S₁−T₁) value by means of the temperature dependence of the emission decay time.

A simple, approximate estimation of the ΔE(S₁−T₁) value can also be made by recording the fluorescence and phosphorescence spectra at low temperature (e.g. 77 K or 4.2 K using a cryostat). The ΔE(S₁−T₁) value then corresponds approximately to the energy difference between the high-energy slope flanks of the fluorescence and phosphorescence bands.

The more marked the CT character of an organic molecule, the greater the variation in the electronic transition energies as a function of solvent polarity. For instance, a marked polarity dependence of the emission energies already gives a pointer to the presence of small ΔE(S₁−T₁) values.

### Additives/Reduction of the Intersystem Crossing Time Constant

Preferred organic molecules consist exclusively of light atoms such as C, H, N, O, F, S, K, Na. For such organic molecules, the electronic singlet and triplet states of which result essentially from transitions between τ and τ* molecular orbitals, as already mentioned, the effective spin-orbit coupling (SOC) is so small that the relaxation transitions from the S₁ to the energetically lower T₁ state and in the reverse direction from the T₁ state to the S₁ state barely occur (are strongly forbidden).

According to the invention, this is no longer forbidden: the organic molecules (emitter molecules), especially those of the formulae I, II and III, may be doped, for example, into optoelectronic devices, or into matrix materials, for example in an OLED emission layer. According to the invention, optically inert atoms or molecules (called “additives”) are added to this matrix to reduce the intersystem crossing time constant of the organic molecule. These optically inert atoms or molecules are notable for high spin-orbit coupling (SOC) (SOC constant of the atoms or molecular units greater than 1000 cm⁻; see the explanations given below). These additives are introduced, for example, in a concentration corresponding to or higher than that of the emitter molecules. These additives can, for example, also be used in a concentration twice to five times as high as that of the organic emitter molecules. In general, the numeric ratio between organic emitter molecules and optically inert atoms or molecules is 1:0.1 to 1:5 or 1:10, preferably 1:0.2 to 1:5, more preferably 1:1. This gives rise to such a distribution probability that at least one additive particle/additive molecule having high SOC is present in the immediate environment of an emitter molecule. This induces external SOC which accelerates the process of intersystem crossing by several orders of magnitude. This brings about very rapid relaxation from the S₁ to the T₁ state and likewise very rapid thermal repopulation according to equations (1) and (2). This enables the singlet harvesting effect for organic molecules.

### Examples of the Additives are:

Noble gases (especially preferred):
   Krypton (Kr), but more preferably xenon (Xe). These gases are introduced during the process for producing an optoelectronic component into the matrix which has been doped with the emitter molecules and is used to form the emission layer. It is necessary in this context to ensure gas saturation at a gas pressure of 1 atmosphere (1013.25 hPa), optionally under elevated gas pressure of up to about 3 atm (approx. 300 kPa), for example of about 2 atm (approx. 200 kPa). The emission layer is applied under this gas atmosphere, for example by means of spin-coating or other wet-chemical processes.
Bromine- and iodine-containing substances, particular preference being given to iodine-containing substances.
Br- or more preferably I-containing substances are added to the solution used to produce the emission layer of an optoelectronic component, for example alkyl bromides, alkyl iodides (e.g. ethyl iodide, propyl iodide), aryl bromide, aryl iodide (e.g. naphthyl iodide).
Optoelectronic devices using these additives are produced by wet-chemical means.
The matrix material of the emission layer of an optoelectronic component may consist of bromine-containing substances, but more preferably of iodine-containing substances or polymer-bound Br or I, or comprise these substances. The halogens may also be present in chemically bonded form in the polymer side groups.
Optoelectronic devices using these additives are produced by wet-chemical means.
Suitable additives are also nanoparticles of metal atoms of the second or preferably third period of the transition metals, or gadolinium. Optoelectronic devices using these additives are produced by wet-chemical means or by means of vacuum or vapor phase deposition processes.
Preferred additives are Gd complexes. These can be added to the solutions of the emission layers used in the production for wet-chemical processing operations, or co-vaporized in the case of production of the optoelectronic devices by means of vacuum sublimation or vapor phase deposition. Particular preference is given to chemically stable Gd complexes which are optically inert within the spectral range required for the application. Examples are: Gd(cyclopentadiene)₃, Gd(tetramethylheptadiene)₃, Gd acetate, Gd(acac)₃, Gd(TMHD)₃, Gd 2-ethylhexanoate etc. Gd ions are considered to be optically inert and can be used in a further aspect of the invention. For example, these Gd ions can also enter into chemical bonds with the organic emitter molecules. For example, Gd complexes can be formed.
Suitable additives are generally atoms or molecules or nanoparticles which do not have any absorptions or emissions in the emission region or relevant HOMO/LUMO region of the emitter, and hence are considered to be optically inert within these regions. The additives, or the atomic constituents thereof, should also have a high SOC constant which is preferably greater than 1000 cm⁻¹, more preferably greater than 3000 cm⁻¹, most preferably greater than 4000 cm⁻¹.

### OLED Devices as Optoelectronic Devices

In a further aspect of the invention, the composition described here is used in an emitter layer in an optoelectronic (organic electronic) device, especially an OLED.

The OLED devices can be produced by processes known from the prior art (cf. H. Yersin, “Highly Efficient OLEDs with Phosphorescent Materials”, Wiley-VCH, Weinheim, Germany 2008).

In a preferred configuration of an organic light-emitting diode (OLED), the proportion of the composition (organic emitter and additive) in the emitter layer is between 2% by weight and 100% by weight, preferably between 6% by weight and 30% by weight.

### Further Optoelectronic Devices

Another aspect of the invention is the use of the inventive composition composed of organic molecule and optically inert atom or optically inert molecule for use in light-emitting electrochemical cells (LEECs), OLED sensors, especially in a gas and vapor sensor not hermetically sealed from the outside, optical temperature sensors, organic solar cells (OSCs; organic photovoltaics, OPVs), organic field-effect transistors, organic diodes, organic photodiodes and “downconversion” systems.

Generally, the proportion of the composition in an emitter layer of an optoelectronic device may be 2 to 100% by weight, preferably 6 to 30% by weight, based on the total weight of the emitter layer.

In a further aspect, the invention relates to a process for reducing the emission lifetime and to a process for increasing the electroluminescence quantum yield of an organic molecule as an emitter in an optoelectronic device. In this case, an organic molecule which has a ΔE(S₁−T₁) value between the lowermost excited singlet state (S₁) and the triplet state (T₁) below it of less than 2500 cm⁻¹ is introduced into the vicinity of an optically inert atom or molecule (optionally via a chemical bond), such that the organic molecule can interact with the optically inert atom or molecule. Due to a spin-orbit coupling constant of greater than 1000 cm⁻¹ for the optically inert atom or molecule or for parts of the optically inert molecule, a short mean emission lifetime (from the singlet S₁ and the triplet T₁ states) of the organic molecule and an increase in the emission quantum yield are achieved.

The invention further relates to a process for converting the triplet excitation energy of an organic molecule generated in the course of electroluminescence to fluorescent energy. This involves interaction of an organic molecule having a ΔE(S₁−T₁) value between the lowermost excited singlet state (S₁) and the triplet state (T₁) below it of less than 2500 cm⁻¹ with an optically inert atom or molecule such that triplet excitation energy of the organic molecule is converted via a singlet state of the organic molecule to fluorescent energy.

The invention also relates to a process for selecting organic molecules for which the ΔE(S₁−T₁) value between the lowermost excited singlet state (S₁) and the triplet state (T₁) below it is less than 2500 cm⁻¹, preferably less than 1500 cm⁻¹, more preferably less than 1000 cm⁻¹. The process comprises at least two steps, namely: firstly the determination of the ΔE(S₁−T₁) value of organic molecules by means of a) an ab initio molecular calculation, b) measurement of the temperature dependence of the fluorescence and phosphorescence intensities, or c) measurement of the temperature dependence of the emission decay time, and secondly the finding of organic molecules for which the ΔE(S1−T1) value is less than 2500 cm⁻¹, preferably less than 1500 cm⁻¹, more preferably less than 1000 cm⁻¹. The organic molecules thus found have a ΔE(S₁−T₁) value between the lowermost excited singlet state (S₁) and the triplet state (T₁) below it of less than 2500 cm⁻¹, preferably less than 1500 cm⁻¹, more preferably less than 1000 cm⁻¹.

### EXAMPLES

From the multitude of realizable organic molecules having a small singlet S₁-triplet T₁ energy difference, using the example of the emitters of the formulae I to III, some examples are given, these having the following properties:
The materials are very good emitters.
The absorption and fluorescence transitions between the S₀ and S₁ states are strongly allowed. Thus, the emission decay times τ(S₁) are very short.
The examples include molecules having emissions from the broad spectral range from the near UV to the near IR range. More particularly, it is thus also possible to realize good blue light emitters.

FIG. 3 (A to I) summarizes various examples.

More particularly, the introduction of above-listed inert additives shows that the intersystem crossing (ISC) times of the transitions between the singlet S₁ and the triplet T₁ of the organic emitter molecules can be drastically reduced or, correspondingly, the ISC rates can be drastically increased. For example, various organic emitter molecules selected from the examples shown in FIG. 3 were applied in pure form, doped in PMMA and by spin-coating, to a glass substrate. In a further test, in addition to the emitter molecules, optically inert additives (e.g. naphthyl iodide or Gd(III) acetate) were introduced in a molar ratio of 1:1 or 1:5 (emitter molecule:additive). Analyses of the changes in the emission characteristics of the two tests show that the additives increase the ISC rates by about a factor of 100 or 1000. This means that the additives do indeed effectively enhance spin-orbit coupling in the emitter molecule.

### FIGURES

FIG. 1: Basic structure of an OLED. The figure is not to scale.

FIG. 2: Illustrations of the electroluminescence characteristics a for typical organic molecules according to the prior art and b for molecules selected in accordance with the invention, which have been modified in their immediate environment by additives in order to enable the “singlet harvesting process for organic molecules”.

FIGS. 3A to I show a list of examples for the organic molecule which is part of the inventive composition.

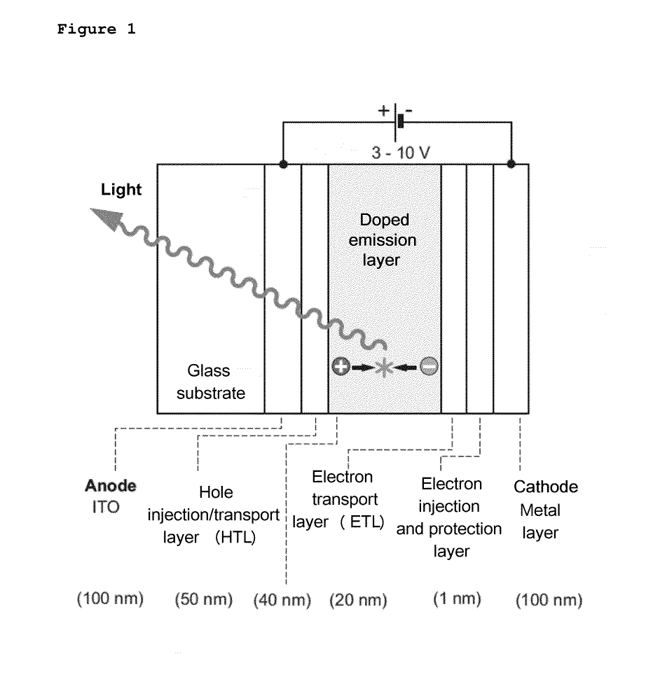

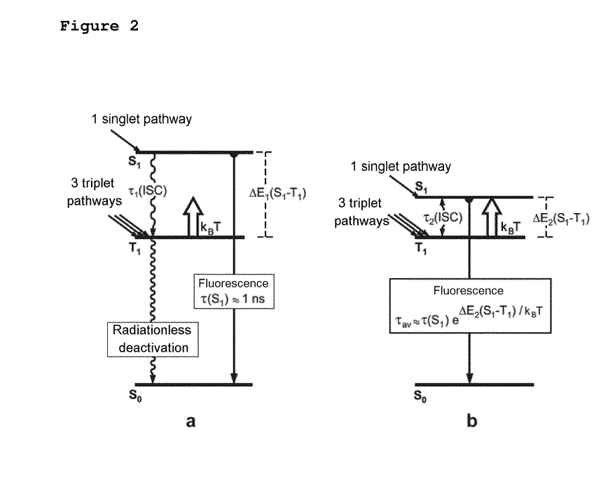

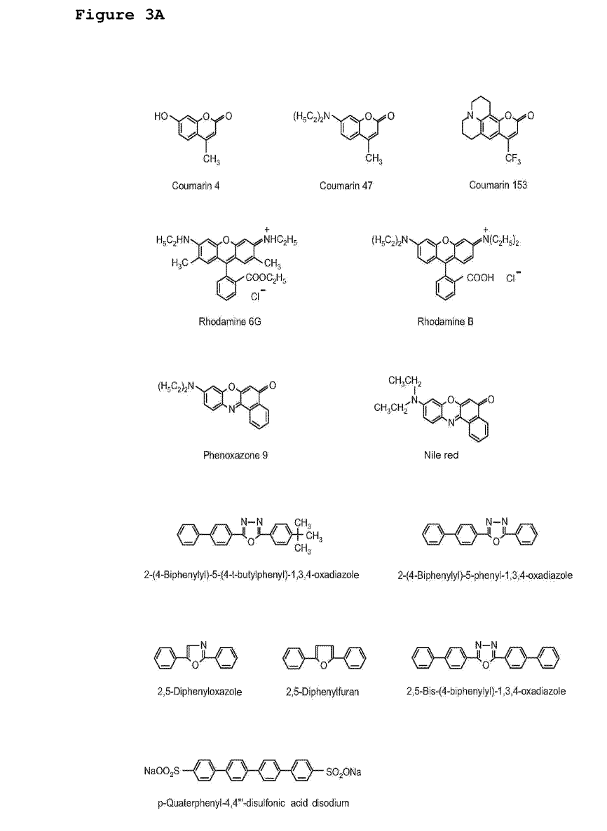

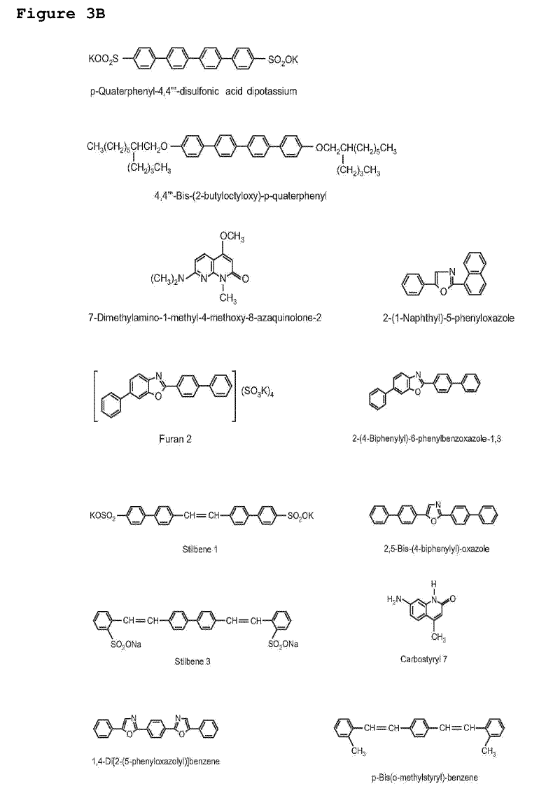

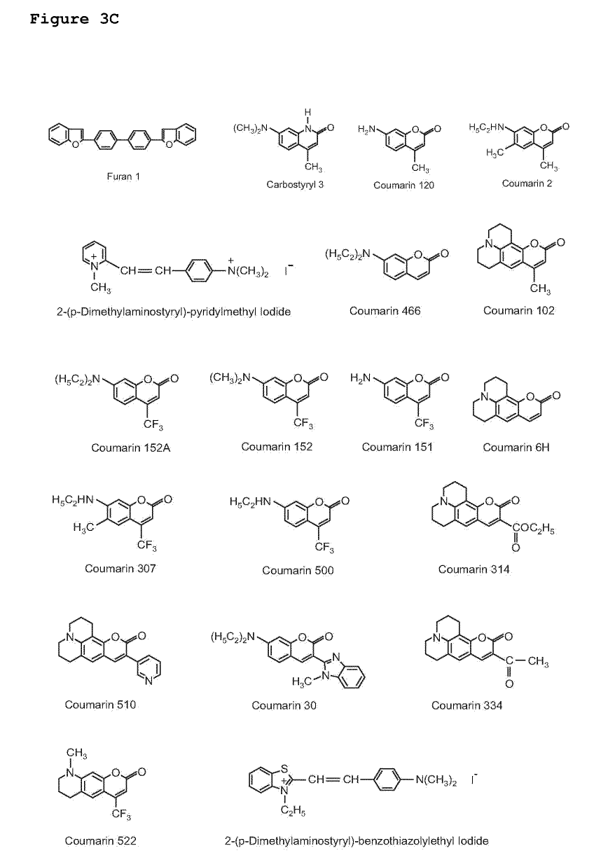

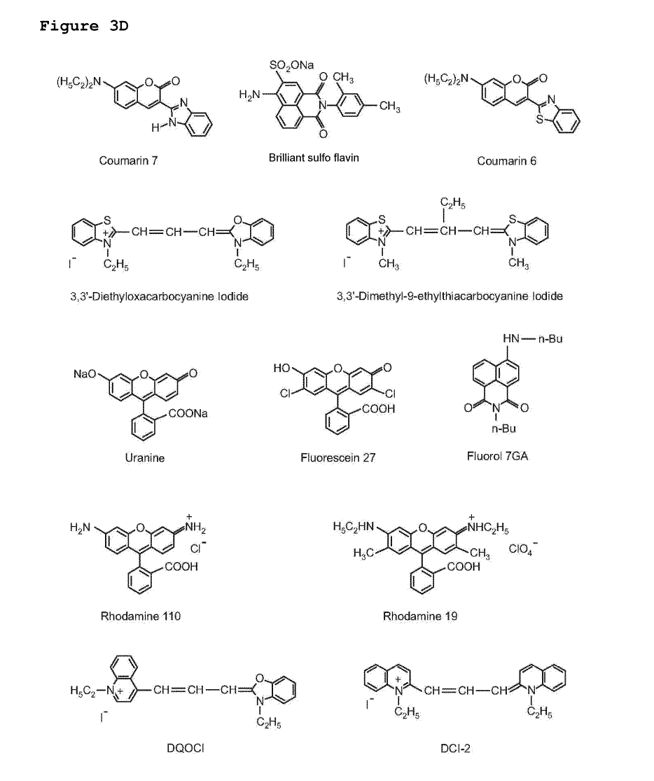

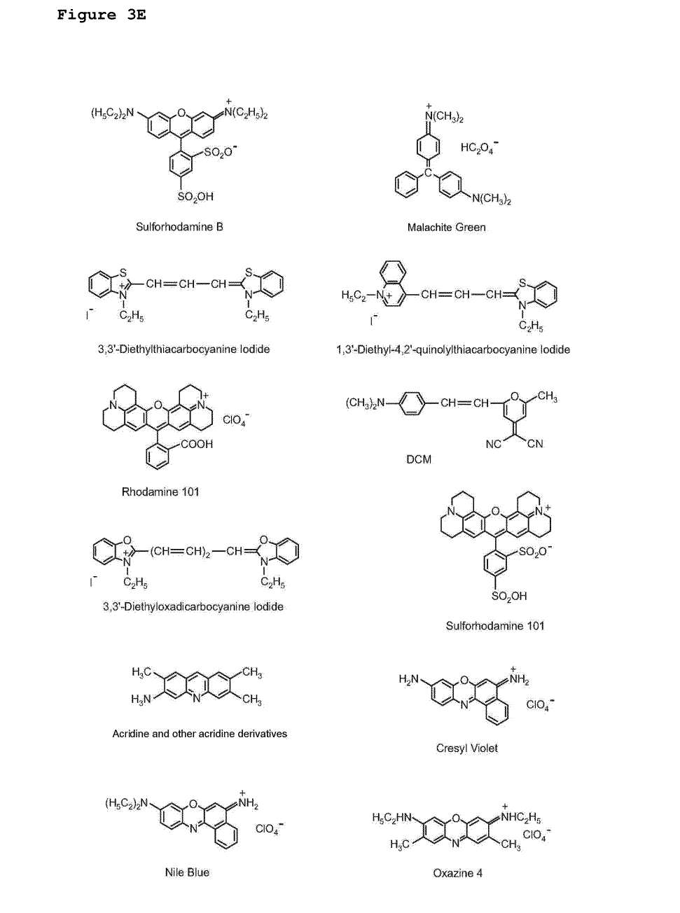

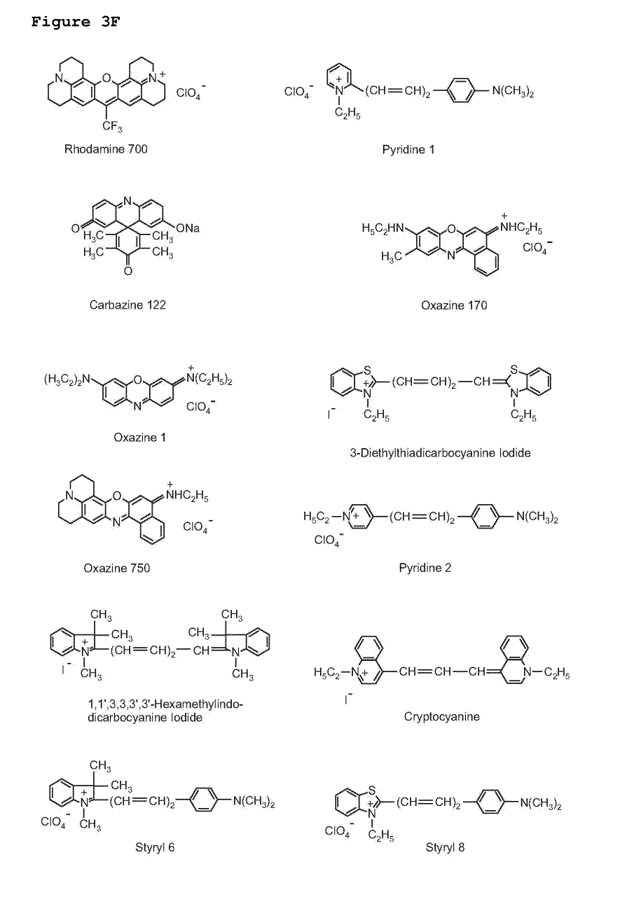

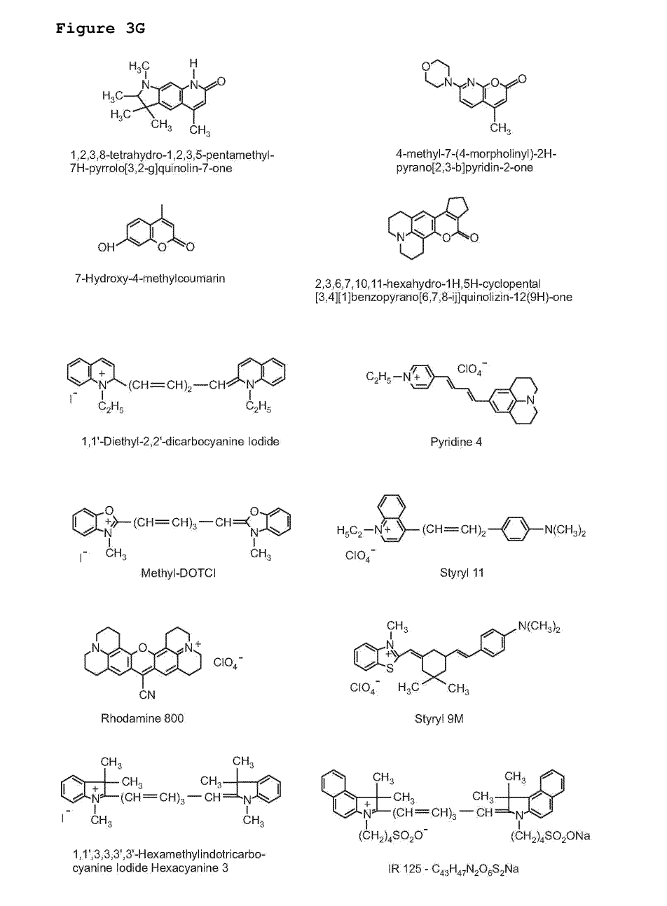

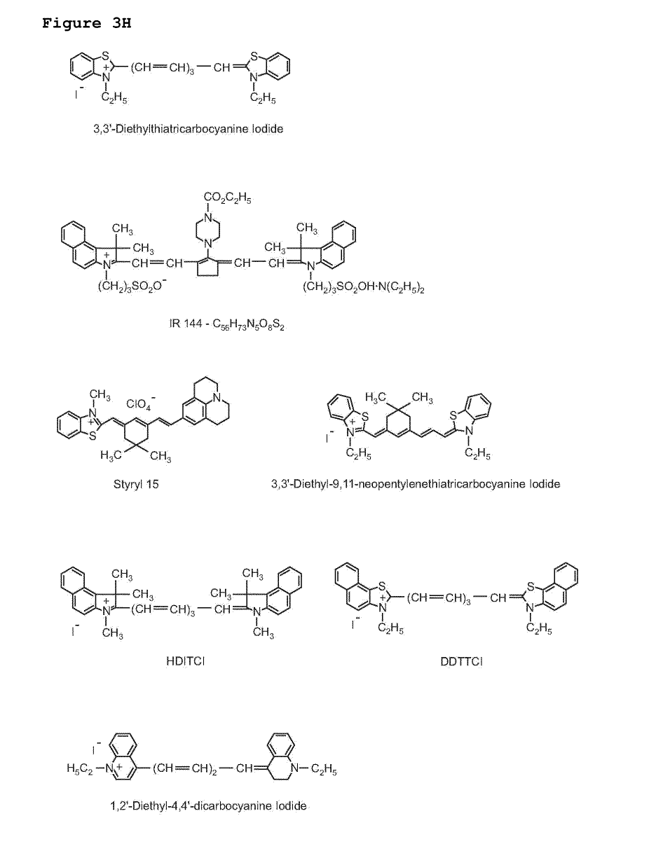

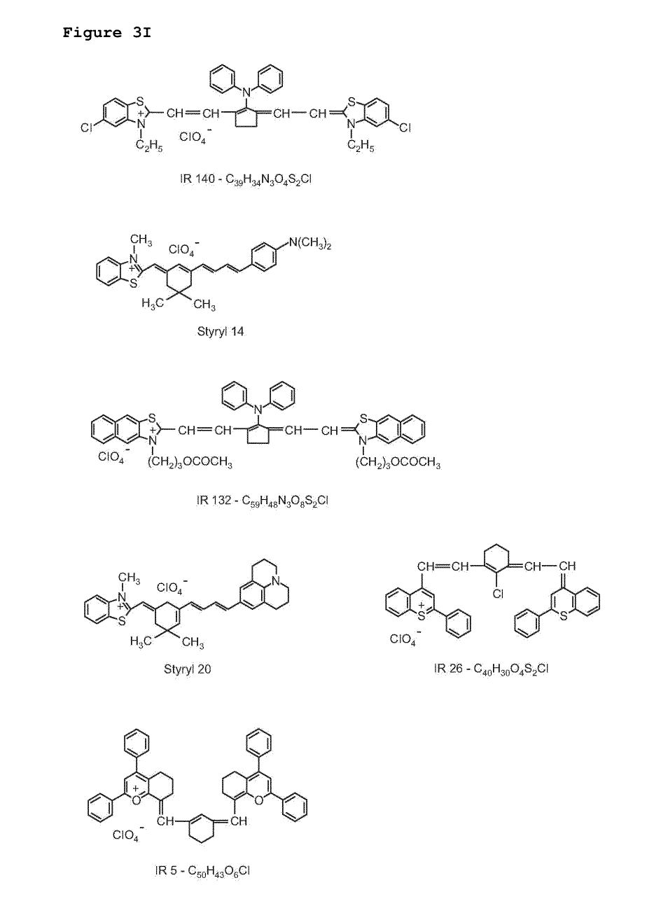

Various examples contain charged organic molecules and counterions. These emitter molecules can preferably be used in light-emitting electrochemical cells (LEECs or LECs), the basic structure of which is known to those skilled in the art. In the case of use of these charged organic molecules in OLEDs, it may be advisable to replace the small counterions with larger counterions of the same charge, such as (PF₆)⁻, (BF₄)⁻, [CF₃SO₂]⁻, singly negatively charged hexaphenylphosphate, singly negatively charged tetraphenylborate, etc.

Some example molecules are apparently of symmetric structure and therefore do not appear to contain any separate D or A groups. These molecules, however, are polarized in solution and/or by the action of the counterions so as to result in corresponding donor or acceptor effects.

1. A composition comprising:
an organic molecule for emission of light, said molecule having a ΔE(S₁−T₁) value between the lowermost excited singlet state (S₁) and the triplet state (T₁) below it of less than 2500 cm⁻¹; and
an optically inert atom or an optically inert molecule for reduction of the intersystem crossing time constant of the organic molecule to less than 10⁻⁶ s.

2-21. (canceled)

22. The composition of claim 1, wherein the optically inert atom or molecule has, or parts of the optically inert molecule have, a spin-orbit coupling constant of greater than 1000 cm⁻¹.

23. The composition of claim 1, wherein the organic molecule in the composition has a ΔE(S₁−T₁) value between the lowermost excited singlet state and the triplet state below it of less than 1500 cm⁻¹.

24. The composition of claim 1, wherein the organic molecule comprises:
at least one conjugated organic group selected from the group consisting of aromatic, heteroaromatic and conjugated double bonds;
at least one chemically bonded donor group having electron-donating action; and
at least one chemically bonded acceptor group having electron-withdrawing action.

25. The composition of claim 1, wherein the organic molecule does not comprise a metal atom or metal ion.

26. The composition of claim 1, wherein the organic molecule is a molecule having the formula of formula I, formula II or formula III: 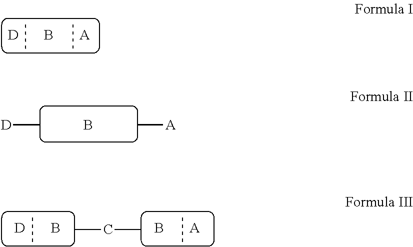
wherein:
D is a chemical group or a substituent having electron-donating propensity which is present once, twice or more than twice and is the same or different;
A is a chemical group or a substituent having electron-withdrawing propensity which is present once, twice or more than twice and may be the same or different;
B is base structure which is formed from conjugated organic groups which consist of aromatic, heteroaromatic and/or conjugated double bonds; and
C is a group which links the base structures B.

27. The composition of claim 1, wherein
the optically inert atom or molecule has no absorptions or emissions within the emission range and/or within the HOMO/LUMO range of the organic molecule.

28. The composition of claim 1, wherein
the optically inert atom or molecule is selected from the group consisting of krypton and xenon noble gases, bromine-containing substances, iodine-containing substances, metal atoms, metal nanoparticles, metal ions and gadolinium complexes.

29. The composition of claim 1, wherein the numerical ratio between organic molecules and optically inert atoms or molecules is 1:0.1 to 1:10.

30. The composition of claim 1, wherein the organic molecule at T=300 K has an emission decay time of less than 5 μs.

31. The composition of claim 1 having an emission quantum yield measured at T=300 K of at least 30%.

32. A process for producing an optoelectronic device, comprising the step of:
providing an emitter layer, wherein the emitter layer comprises the composition of claim 1.

33. The process of claim 32, wherein krypton or xenon is used as the inert atom in the form of a gas under standard pressure up to 300 kPa.

34. The process of claim 32, wherein the optoelectronic device is selected from the group consisting of organic light-emitting diodes (OLEDs), light-emitting electrochemical cells (LEECs or LECs), OLED sensors, optical temperature sensors, organic solar cells (OSCs), organic field-effect transistors, organic lasers, organic diodes, organic photodiodes and organic downconversion systems.

35. An optoelectronic device comprising:
an emitter layer, wherein the emitter layer comprises the composition of claim 1.

36. The optoelectronic device of claim 35, wherein
the proportion of the composition in the emitter layer is 2 to 100% by weight, based on the total weight of the emitter layer.

37. The optoelectronic device of claim 35, wherein the optoelectronic device is selected from the group consisting of organic light-emitting diodes (OLEDs), light-emitting electrochemical cells (LEECs or LECs), OLED sensors, optical temperature sensors, organic solar cells (OSCs), organic field-effect transistors, organic lasers, organic diodes, organic photodiodes and organic downconversion systems.

38. The optoelectronic device of claim 37, wherein
the proportion of the composition in the emitter layer is 2 to 100% by weight, based on the total weight of the emitter layer.

39. A process for reducing emission lifetime and for increasing electroluminescence quantum yield in an optoelectronic device, comprising the steps of:
(i) providing an organic molecule, the organic molecule having a ΔE(S₁−T₁) value between the lowermost excited singlet state and the triplet state below of less than 2500 cm⁻¹;
(ii) adding an optically inert atom or molecule to the organic molecule; and
(iii) using the organic molecule as an emitter in the optoelectronic device, wherein:
the optically inert atom or molecule interacts with the organic molecule, and
the optically inert atom or molecule has, or parts of the optically inert molecule have, a spin-orbit coupling constant of greater than 1000 cm⁻¹.

40. The process of claim 39, wherein the optoelectronic device is selected from the group consisting of organic light-emitting diodes (OLEDs), light-emitting electrochemical cells (LEECs or LECs), OLED sensors, optical temperature sensors, organic solar cells (OSCs), organic field-effect transistors, organic lasers, organic diodes, organic photodiodes and organic downconversion systems.

41. A process for converting the triplet excitation energy of an organic molecule generated in the course of electroluminescence to fluorescence energy, comprising the step of:
interacting an organic molecule having a ΔE(S₁−T₁) value between the lowermost excited singlet state (S₁) and the triplet state (T₁) below it of less than 2500 cm⁻¹ with an optically inert atom or molecule such that any triplet excitation energy of the organic molecule is converted to fluorescent energy via a singlet state of the organic molecule.
